(19) United States
(12) Patent Application Publication
(10) Pub. No.: US 2019/0084829 A1
(43) Pub. Date: Mar. 21, 2019

(54) PATTERN FORMATION METHOD AND PATTERN FORMATION MATERIAL

(71) Applicant: TOSHIBA MEMORY CORPORATION, Tokyo (JP)

(72) Inventors: Norikatsu SASAO, Kawasaki Kanagawa (JP); Koji Asakawa, Kawasaki Kanagawa (JP); Seekei Lee, Kawasaki Kanagawa (JP); Naoko Kihara, Kawasaki Kanagawa (JP); Tomoaki Sawabe, Taito Tokyo (JP); Shinobu Sugimura, Yokohama Kanagawa (JP)

(73) Assignee: TOSHIBA MEMORY CORPORATION, Tokyo (JP)

(21) Appl. No.: 15/917,053

(22) Filed: Mar. 9, 2018

(30) Foreign Application Priority Data
Sep. 20, 2017 (JP) 2017-180577

(51) Int. Cl. B81C 1/00; B32B 27/30

(52) U.S. Cl. CPC B81C 1/00531; B81C 1/00111; B32B 27/306; C01G 23/02; B32B 27/302; B81C 2201/0132; B32B 27/304

(57) ABSTRACT

According to one embodiment, a pattern formation method is disclosed. The method can include a preparation process, a first layer formation process, a block copolymer layer formation process, and a contact process. The preparation process prepares a pattern formation material including a polymer including a first chemical structure including carbon, hydrogen, and a first group. The first group includes one of a vinyl group, a hydroxy group, or a first element. The first layer formation process forms a first layer on a base body. The first layer includes the pattern formation material. The block copolymer layer formation process forms a block copolymer layer on the first layer. The block copolymer layer includes a first polymer and a second polymer. The block copolymer layer formation process includes forming first and second regions. The contact process causes the block copolymer layer to contact a metal compound including a metallic element.

### CROSS-REFERENCE TO RELATED APPLICATIONS

This application is based upon and claims the benefit of priority from Japanese Patent Application No. 2017-180577, filed on Sep. 20, 2017; the entire contents of which are incorporated herein by reference.

### FIELD

Embodiments described herein relate generally to a pattern formation method and a pattern formation material.

### BACKGROUND

For example, there is a method for forming a pattern by directed self-assembly (DSA) of a block copolymer, etc. It is desirable to improve the productivity of the pattern formation method and the pattern formation material.

### BRIEF DESCRIPTION OF THE DRAWINGS

FIG. 1A and FIG. 1B are schematic views illustrating a pattern formation material used in the pattern formation method according to the first embodiment;

FIG. 2 is a schematic view illustrating the block copolymer used in the pattern formation method according to the first embodiment;

FIG. 3A to FIG. 3F are schematic cross-sectional views illustrating the pattern formation method according to the first embodiment; and

FIG. 4 is a graph illustrating the experimental results relating to the pattern formation material.

### DETAILED DESCRIPTION

According to one embodiment, a pattern formation method is disclosed. The method can include a preparation process, a first layer formation process, a block copolymer layer formation process, and a contact process. The preparation process prepares a pattern formation material including a polymer including a first chemical structure including carbon, hydrogen, and a first group. The first group includes at least one of a vinyl group, a hydroxy group, or a first element. The first element includes at least one selected from the group consisting of fluorine, chlorine, and bromine. The pattern formation material does not include a carbonyl group, or a concentration of carbonyl groups in the pattern formation material is 0.0005 mol/g or less. The first layer formation process forms a first layer on a base body. The first layer includes the pattern formation material. The block copolymer layer formation process forms a block copolymer layer on the first layer. The block copolymer layer includes a first polymer and a second polymer. The block copolymer layer formation process includes forming a first region and a second region by causing phase separation of the first polymer and the second polymer. The first region includes the first polymer, the second region including the second polymer. The second polymer includes a carbonyl group. The contact process causes the block copolymer layer to contact a metal compound including a metallic element.

According to another embodiment, a pattern formation material includes a polymer, and a solvent. The polymer includes a first chemical structure including carbon, hydrogen, and a first group. The first group includes at least one of a vinyl group, a hydroxy group, or a first element. The first element includes at least one of a fluorine atom, a chlorine atom, a bromine atom, or a nitrogen atom. The pattern formation material does not include a carbonyl group, or a concentration of carbonyl groups in the pattern formation material is 0.0005 mol/g or less.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing hereinabove are marked with like reference numerals, and a detailed description is omitted as appropriate.

### First Embodiment

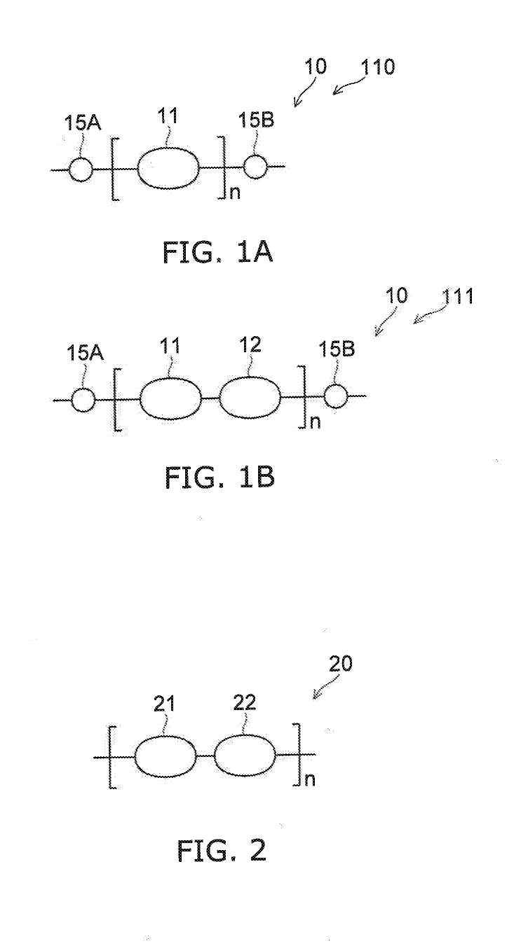

FIG. 1A and FIG. 1B are schematic views illustrating a pattern formation material used in the pattern formation method according to the first embodiment.

As shown in FIG. 1A, the pattern formation material 110 includes a polymer 10. The polymer 10 includes, for example, a first chemical structure 11. The chemical structure 11 is produced, for example by polymerizing the precursor monomer. The polymer 10 has, for example, a first terminal 15A and a second terminal 15B.

In a pattern formation material 111 as shown in FIG. 1B, the polymer 10 includes, for example, the first chemical structure 11 and a second chemical structure 12. In such a case, the polymer 10 includes a random copolymer including the first chemical structure 11 and the second chemical structure 12. The chemical structure 11 and the chemical structure 12 are produced, for example by polymerizing the precursor monomers.

The first chemical structure 11 includes carbon, hydrogen, and a first group.

The first group includes at least one of a vinyl group, a hydroxy group, or a first element. The first element includes at least one of fluorine, chlorine, or bromine.

The first group includes, for example, at least one selected from the group consisting of vinyl alcohol, hydroxystyrene, and vinyl chloride.

For example, the first group substantially does not include a carbonyl group. The pattern formation material (the pattern formation material 110, 111, or the like) substantially does not include a carbonyl group. For example, the pattern formation material (the pattern formation material 110, 111, or the like) does not include a carbonyl group. Or, the pattern formation material (the pattern formation material 110, 111, or the like) includes a carbonyl group; and the concentration of carbonyl groups in the pattern formation material is 0.0005 mol/g or less.

As described below, for example, the pattern formation material 110 is used as a surface treatment layer for a block copolymer to undergo directed self-assembly, etc. The surface energy of the polymer 10 included in the pattern formation material 110 is adjusted to be between the surface energies of the multiple polymers included in the block copolymer. It is possible to adjust the surface energy by selecting certain functional groups for the first group.

In the case where the polymer 10 includes the first chemical structure 11 and the second chemical structure 12 as in the pattern formation material 111, the second chemical structure 12 includes, for example, at least one selected from the group consisting of styrene, isobutylene, butadiene, and isoprene.

For example, the first group included in the first chemical structure 11, the second chemical structure 12, and the composition ratio of these substances are appropriately adjusted. Thereby, it is possible to adjust the surface energy.

As described above, the polymer 10 has the first terminal 15A. The first terminal 15A includes, for example, at least one selected from the group consisting of a hydroxy group, a thiol group, a trimethylsilyl group, and a hydrocarbon including a nitroxyl radical. The second terminal 15B of the polymer 10 includes, for example, at least one selected from the group consisting of a hydroxy group, a thiol group, a trimethylsilyl group, and a hydrocarbon including a nitroxyl radical. The first terminal 15A may be the same as or different from second terminal 15B.

By providing the first terminal 15A and the second terminal 15B to have the structures recited above, these terminals adsorb (bind) stably to the base body. A film that includes the pattern formation material can be formed stably.

The pattern formation material (the pattern formation materials 110, 111, or the like) according to the embodiment may further include a solvent. The solvent includes, for example, at least one selected from the group consisting of PGMEA (propyleneglycol monomethyl ether acetate), anisole, ethyl lactate, butyl acetate, and cyclohexanone. The concentration of the polymer 10 in the pattern formation material is, for example, not less than 0.001 wt % and not more than 20 wt %. By appropriately setting the solvent and the concentration, a uniform film that includes the pattern formation material is formed.

For example, the polymer 10 that is included in the pattern formation material according to the embodiment can be represented by the following first chemical formula.

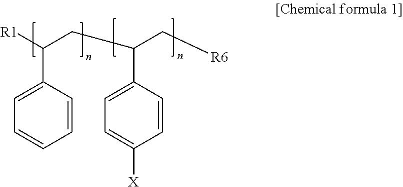

In the first chemical formula recited above, at least one of “R1” or “R6” is a hydrocarbon group including the groups represented by the following second to fifteenth chemical formulas.

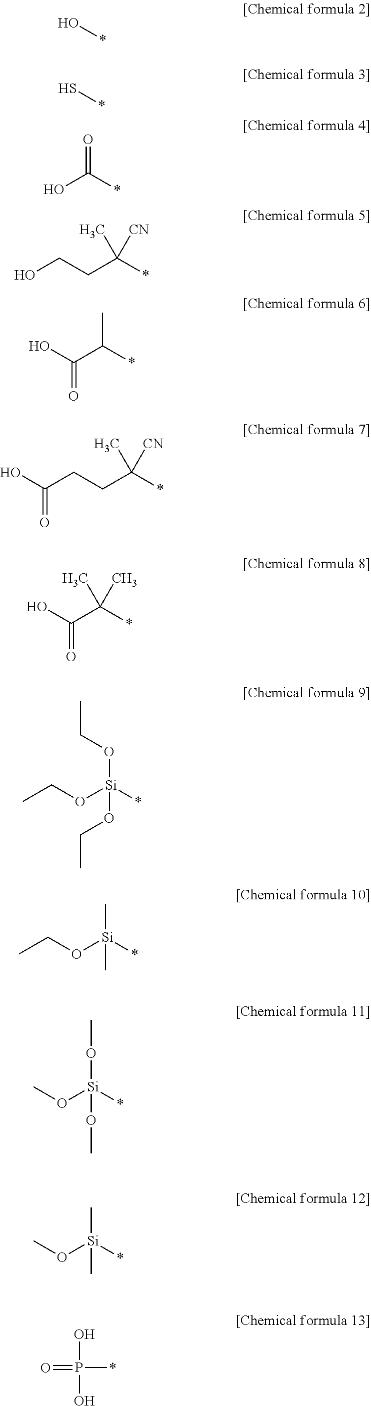

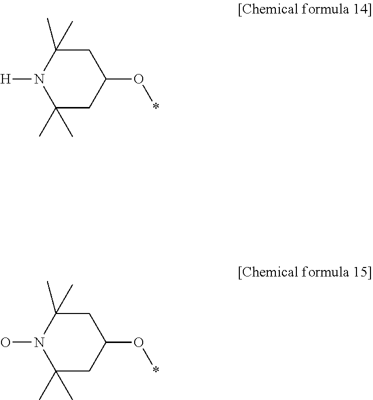 [SMILES: *OC1CC(C)(C)NC(C)(C)C1 ; *OC1CC(C)(C)N(O)C(C)(C)C1]

In the first chemical formula recited above, “X” is one selected from the group consisting of a hydroxy group, chlorine, fluorine, and bromine.

Examples of the block copolymer layer formed on the film of the pattern formation material according to the embodiment will now be described.

FIG. 2 is a schematic view illustrating the block copolymer used in the pattern formation method according to the first embodiment.

As shown in FIG. 2, the block copolymer 20 includes a first polymer 21 and a second polymer 22. The block copolymer 20 is, for example, a diblock copolymer. The second polymer 22 is different from the first polymer 21. The second polymer 22 includes, for example, a carbonyl group. On the other hand, the first polymer 21 does not include a carbonyl group.

For example, the first polymer 21 includes PS (polystyrene). The second polymer 22 includes PMMA (polymethyl methacrylate). The surface energies of these polymers are different from each other. Therefore, by providing a layer of a block copolymer including these polymers on an appropriate surface treatment layer, for example, these polymers phase-separate by directed self-assembly. For example, a lamella that includes the first polymer 21 and a lamella that includes the second polymer 22 are arranged on the surface treatment layer perpendicular to the base body. The surface energy of the appropriate surface treatment layer is set between the surface energies of these polymers.

An example of a pattern formation method using such a pattern formation material and such a block copolymer will now be described. A graphoepitaxy guide is used in the following pattern formation method. A chemoepitaxy guide may be used in the embodiment.

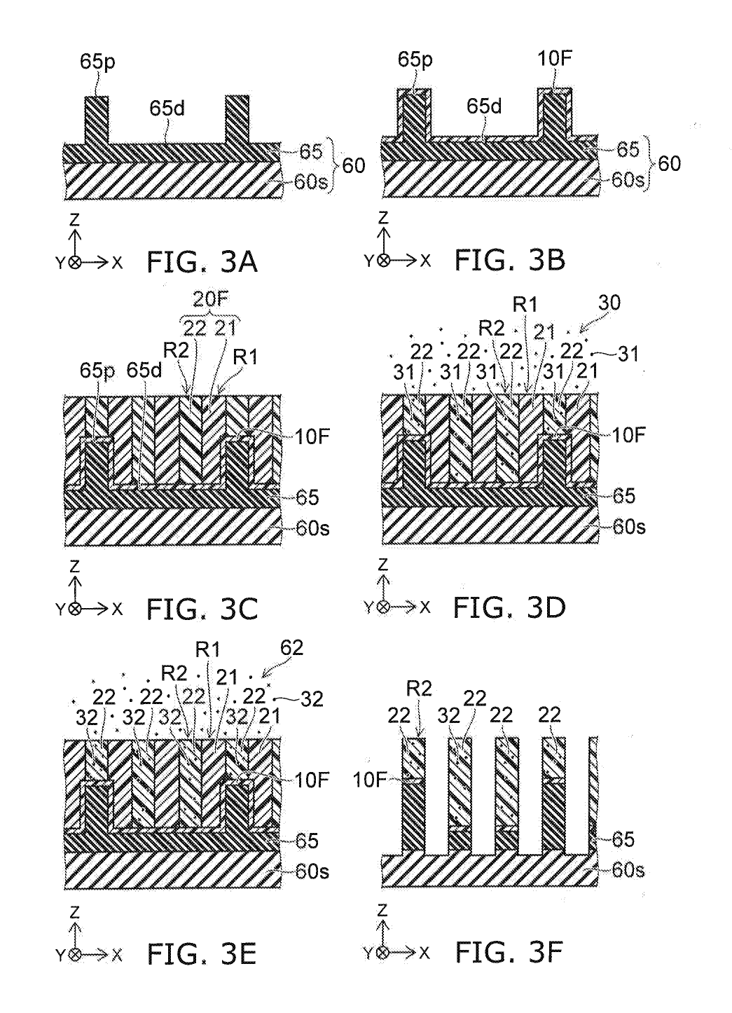

FIG. 3A to FIG. 3F are schematic cross-sectional views illustrating the pattern formation method according to the first embodiment.

As shown in FIG. 3A, a graphoepitaxy guide 65 is formed on a substrate 60s. The graphoepitaxy guide 65 includes a projection 65p and a recess 65d. The graphoepitaxy guide 65 includes, for example, a thermocurable resin or a photocurable resin. For example, the graphoepitaxy guide 65 may be formed by photolithography and etching.

The substrate 60s and the graphoepitaxy guide 65 are used as a base body 60. The base body 60 spreads along the X-Y plane. A direction perpendicular to the X-Y plane is taken as a Z-axis direction. The position in the Z-axis direction of the top portion of the projection 65p is different from the position in the Z-axis direction of the recess 65d.

As shown in FIG. 3B, a first layer 10F is formed on the base body 60. The first layer 10F includes the pattern formation material (the pattern formation material 110, 111, or the like) according to the embodiment. The first layer 10F is provided on the surfaces (the top surface and the side surface) of the projection 65p and the surface of the recess 65d. For example, the first layer 10F covers these surfaces.

For example, a liquid of the pattern formation material is coated onto the surface of the projection 65p. The coating method includes, for example, any method such as inkjet, dip coating, bar coating, spin coating, etc. Thermal treatment is performed if necessary. Thereby, the first layer 10F is formed. Thus, in the embodiment, a first layer formation process of forming the first layer 10F on the base body 60 is performed.

As shown in FIG. 3C, a block copolymer layer 20F is formed on the first layer 10F. The block copolymer layer 20F includes the first polymer 21 and the second polymer 22. The surface energy of the first layer 10F is larger than the surface energy of the first polymer 21 (e.g., PS) and smaller than the surface energy of the second polymer 22 (e.g., PMMA). The first layer 10F functions as, for example, a neutralization layer.

For example, phase separation of the first polymer 21 and the second polymer 22 is caused by heat treatment, etc. Thereby, a first region R1 that includes the first polymer 21 is formed; and a second region R2 that includes the second polymer 22 is formed. The first region R1 and the second region R2 each are aligned perpendicularly to the major surface of the base body 60. For example, the direction from the first region R1 toward the second region R2 is along the base body 60. The direction from the first region R1 toward the second region R2 is along the X-Y plane. Thus, a block copolymer layer formation process is performed.

In the example, the second region R2 is positioned on the projection 65p. Sets of one first region R1 and one second region R2 are arranged between two projections 65p. The pitch of the sets of one first region R1 and one second region R2 is smaller than the pitch of the projections 65p.

As shown in FIG. 3D, the block copolymer layer 20F is caused to contact a metal compound 30 including a metallic element 31. Thus, a contact process is performed.

The metal compound 30 includes, for example, an organic metal compound. The metal compound 30 includes, for example, trimethyl aluminum. The metal compound 30 may include chlorine and at least one selected from the group consisting of Ti, V, and W. For example, at least one selected from the group consisting of TiCl₄, VCl₄, and WCl₆ may be included. For example, the first metallic element 31 includes at least one selected from the group consisting of Al, Ti, V, and W.

The contact process includes, for example, causing the block copolymer layer 20F to contact at least one of a liquid including the metal compound 30 or a gas including the metal compound 30. Thereby, the metal compound 30 is introduced to at least a portion of the block copolymer layer 20F. For example, the metal compound 30 diffuses into the second region R2. At this time, the metal compound 30 may also diffuse into the first region R1.

The structure of the first polymer 21 of the first region R1 is different from the structure of the second polymer 22 of the second region R2. For example, the polarity of the second region R2 is higher than the polarity of the first region R1. For example, the concentration of the metal compound 30 introduced to the second region R2 may be higher than the concentration of the metal compound 30 introduced to the first region R1. The contact process includes, for example, introducing the metal compound 30 to the second region R2.

As described above, the second polymer 22 of the second region R2 includes a carbonyl group. As described below, the metallic element 31 that is included in the metal compound 30 is readily adsorbed to the carbonyl group. Therefore, the concentration of the metallic element 31 in the second region R2 including the second polymer 22 easily becomes high. On the other hand, the concentration of the metallic element 31 is low in the first region R1 including the first polymer 21 that does not include a carbonyl group. The pattern formation material (the pattern formation material 110, 111, or the like) substantially does not include a carbonyl group. Therefore, the concentration of the metallic element 31 in the first layer 10F of the pattern formation material is low.

After the contact process, the concentration of the metallic element 31 in the first region R1 is lower than the concentration of the metallic element 31 in the second region R2. Further, the concentration of the metallic element 31 in the first layer 10F is lower than the concentration of the metallic element 31 in the second region R2.

After the contact process recited above as shown in FIG. 3E, the block copolymer layer 20F is exposed to an atmosphere 62 including at least one selected from the group consisting of water, oxygen including a plasma state, and ozone. This process is, for example, an oxidation process.

Thereby, after the process, the second region R2 includes an oxide 32 including the metallic element 31. On the other hand, the oxide 32 that includes the metallic element 31 is substantially not formed in the first region R1 and the first layer 10F.

The oxide 32 that includes the metallic element 31 includes, for example, at least one selected from the group consisting of aluminum oxide, titanium oxide, vanadium oxide, and tungsten oxide.

By such an oxide 32, the etching resistance of the second region R2 is higher than the etching resistance of the first region R1. The etching rate of the second region R2 is lower than the etching rate of the first region R1. The etching rate of the second region R2 is lower than the etching rate of the first layer 10F.

After the process recited above as shown in FIG. 3F, the first region R1 is removed; and the portion of the first layer 10F overlapping the first region R1 is removed. As described above, the etching rate of the second region R2 is lower than the etching rate of the first region R1 and lower than the etching rate of the first layer 10F. Therefore, the second region R2 remains. The second region R2 includes the oxide 32 including the metallic element 31.

At least a portion of the base body 60 not overlapping the second region R2 is also removed.

A first removal of the first region R1 and the portion of the first layer 10F overlapping the first region R1 and a second removal of the at least one portion of the base body 60 not overlapping the second region R2 may be performed continuously. For example, these removals are performed by RIE (Reactive Ion Etching), etc. The etching conditions of the first removal may be different from the etching conditions of the second removal.

In the embodiment, the oxide 32 is not produced in the first layer 10F since it substantially does not include a carbonyl group. Therefore, the first layer 10F has a high etching rate. On the other hand, a low etching rate is obtained for the second region R2 including the carbonyl group. Therefore, the second region R2 remains with high precision. Thereby, a pattern having high precision can be obtained with high productivity.

In the contact process recited above, the metal compound 30 that includes the metallic element 31 contacts the block copolymer layer 20F. It was found that in such a case, the metal compound 30 is adsorbed to (which may include binding to) the carbonyl group. For example, by calculations using a quantum chemical calculation program (Gaussian, etc.), it was found that the metallic element 31 (e.g., Al) of the metal compound 30 is adsorbed (bound) more readily to a carbonyl group than to a hydrocarbon or an ether group.

In the embodiment, after the contact process, for example, the metallic element 31 is adsorbed to (which may include bound to) the carbonyl group.

Therefore, the metallic element 31 (e.g., Al) of the metal compound 30 exists at a high concentration in the second region R2 including the carbonyl group. On the other hand, the concentration of the metallic element 31 in the first region R1 is low.

In the embodiment, the pattern formation material of the first layer 10F does not include a carbonyl group. Therefore, the concentration of the metallic element 31 in the first layer 10F is low.

By using the pattern formation material according to the embodiment, the first layer 10F can be removed by etching when removing the first region R1. Thereby, etching in which the second region R2 is used as a mask can be performed effectively.

For example, the concentration of carbonyl groups in PMMA is about 0.01 mol/g. On the other hand, the pattern formation material (the pattern formation material 110, 111, or the like) according to the embodiment does not include a carbonyl group. Or, the pattern formation material (the pattern formation material 110, 111, or the like) according to the embodiment includes a carbonyl group; and the concentration of carbonyl groups in the pattern formation material is 0.0005 mol/g or less. The concentration of carbonyl groups in the pattern formation material may be 0.00005 mol/g or less. The concentration of carbonyl groups in the pattern formation material may be 0.000005 mol/g or less. For example, the concentration of the metallic element 31 in the first layer 10F can be set to be low.

An example of experimental results relating to the expansion ratio of the pattern formation material will now be described.

In the experiment, the process described in reference to FIG. 3A to FIG. 3E is performed on the pattern formation material. A film of the pattern formation material having a predetermined thickness is formed. The film thickness of the pattern formation material before the contact process of causing contact with the metal compound 30 including the metallic element 31 is taken as a first value U. On the other hand, the film thickness of the pattern formation material after the processing in the atmosphere 62 including at least one selected from the group consisting of water, oxygen including a plasma state, and ozone is taken as a second value t2. The ratio (t2/t1) of the second value t2 to the first value t1 is taken as an expansion ratio RE. For example, after the processing in the atmosphere 62, the volume of the pattern formation material expands when the metal compound 30 including the metallic element 31 diffuses into the pattern formation material. In such a case, the second value t2 becomes larger than the first value t1. A large expansion ratio RE corresponds to large amount of metal compound 30 diffused in to the pattern formation material. A large expansion ratio RE corresponds to a large degree of metallization.

The results of first to fourth samples SP01 to SP04 of the pattern formation material will now be described. The first sample SP01 is polystyrene. The second sample SP02 is polyhydroxystyrene. The first sample SP01 and the second sample SP02 do not include a carbonyl group in the polymer structures. The third sample SP03 is poly(methyl methacrylate). The fourth sample SP04 is polyvinyl acetate. The third sample SP03 and the fourth sample SP04 include carbonyl groups in the polymer structures.

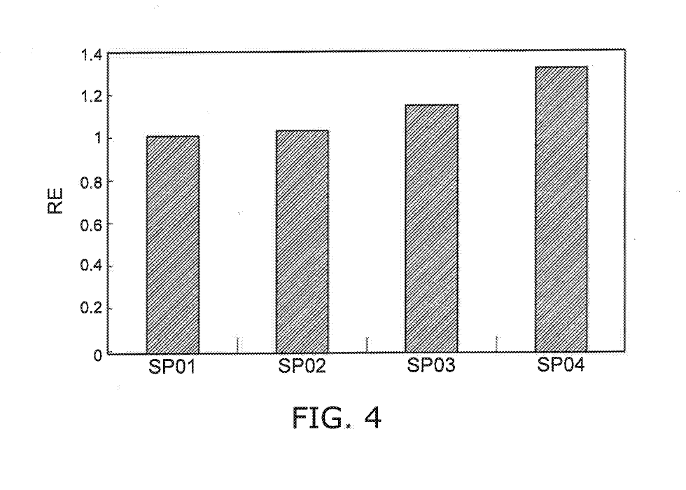

FIG. 4 is a graph illustrating the experimental results relating to the pattern formation material.

The vertical axis of FIG. 4 is the expansion ratio RE. The expansion ratio RE is shown in FIG. 4 for the first to fourth samples SP01 to SP04.

The expansion ratios RE of the third sample SP03 and the fourth sample SP04 are higher than the expansion ratios RE of the first sample SP01 and the second sample SP02. The expansion ratio RE for the materials including a carbonyl in the polymer structure is higher than the expansion ratio RE for the materials that does not include a carbonyl in the polymer structure.

From the results of FIG. 4, it can be seen that metallization occurs readily in the case where a carbonyl group is included in the chemical structure of the polymer included in the pattern formation material.

### Second Embodiment

A second embodiment relates to a pattern formation material. The pattern formation material includes the polymer 10 (referring to FIG. 1A and FIG. 1B) and a solvent. The polymer 10 includes the first structure 11. The first chemical structure 11 includes carbon, hydrogen, and a first group. The first group includes at least one of a vinyl group, a hydroxy group, or a first element. The first element includes at least one of fluorine, chlorine, or bromine.

The first group includes, for example, at least one selected from the group consisting of vinyl alcohol, hydroxystyrene, and vinyl chloride. The pattern formation material according to the embodiment does not include a carbonyl group. Or, the concentration of carbonyl groups in the pattern formation material is 0.0005 mol/g or less.

The polymer 10 may further include the second chemical structure 12. The second chemical structure 12 includes, for example, at least one selected from the group consisting of styrene, isobutylene, butadiene, and isoprene. The polymer 10 may include a random copolymer including the first chemical structure 11 and the second chemical structure 12. For example, the polymer 10 has the first terminal 15A; and the first terminal 15A includes at least one selected from the group consisting of a hydroxy group, a thiol group, a trimethylsilyl group, and a hydrocarbon including a nitroxyl radical. The solvent includes, for example, at least one selected from the group consisting of PGMEA (propyleneglycol monomethyl ether acetate), anisole, ethyl lactate, butyl acetate, and cyclohexanone. The concentration of the polymer 10 in the pattern formation material is, for example, not less than 0.001 wt % and not more than 20 wt %.

The embodiments may include the following configurations (e.g., technological proposals).

### Configuration 1

A pattern formation method, comprising:

a preparation process of preparing a pattern formation material including a polymer including a first chemical structure, the first chemical structure including carbon, hydrogen, and a first group, the first group including at least one of a vinyl group, a hydroxy group, or a first element, the first element including at least one selected from the group consisting of fluorine, chlorine, and bromine, the pattern formation material not including a carbonyl group, or a concentration of carbonyl groups in the pattern formation material being 0.0005 mol/g or less;

a first layer formation process of forming a first layer on a base body, the first layer including the pattern formation material;

a block copolymer layer formation process of forming a block copolymer layer on the first layer, the block copolymer layer including a first polymer and a second polymer, the block copolymer layer formation process including forming a first region and a second region by causing phase separation of the first polymer and the second polymer, the first region including the first polymer, the second region including the second polymer, the second polymer including a carbonyl group; and

a contact process of causing the block copolymer layer.

### Configuration 2

The pattern formation method according to Configuration 1, wherein the first group includes at least one selected from the group consisting of vinyl alcohol, hydroxystyrene, and vinyl chloride.

### Configuration 3

The pattern formation method according to Configuration 1 or 2, wherein
the polymer further includes a second chemical structure, and
the second chemical structure includes at least one selected from the group consisting of styrene, isobutylene, butadiene, and isoprene.

### Configuration 4

The pattern formation method according to Configuration 3, wherein the polymer includes a random copolymer including the first chemical structure and the second chemical structure.

### Configuration 5

The pattern formation method according to any one of Configurations 1 to 4, wherein

the polymer has a first terminal, and

the first terminal includes at least one selected from the group consisting of a hydroxy group, a thiol group, a trimethylsilyl group, and a hydrocarbon including a nitroxyl radical.

### Configuration 6

The pattern formation method according to any one of Configurations 1 to 5, wherein

the pattern formation material further includes a solvent,

the solvent includes at least one selected from the group consisting of PGMEA (propyleneglycol monomethyl ether acetate), anisole, ethyl lactate, butyl acetate, and cyclohexanone, and

a concentration of the polymer in the pattern formation material is not less than 0.001 wt % and not more than 20 wt %.

### Configuration 7

The pattern formation method according to any one of Configurations 1 to 6, wherein the contact process includes introducing the metal compound to the second region.

### Configuration 8

The pattern formation method according to any one of Configurations 1 to 7, wherein the contact process includes causing the block copolymer layer to contact at least one of a liquid including the metal compound or a gas including the metal compound.

### Configuration 9

The pattern formation method according to any one of Configurations 1 to 8, wherein after the contact process, a concentration of the metallic element in the first region is lower than a concentration of the metallic element in the second region, and a concentration of the metallic element in the first layer is lower than the concentration of the metallic element in the second region.

### Configuration 10

The pattern formation method according to any one of Configurations 1 to 9, wherein after the contact process, the metallic element is adsorbed to the carbonyl group.

### Configuration 11

The pattern formation method according to any one of Configurations 1 to 10, further comprising, after the contact process, an exposure process of the block copolymer layer in an atmosphere including at least one selected from the group consisting of water, oxygen including a plasma state, and ozone.

### Configuration 12

The pattern formation method according to Configuration 11, wherein after the process, the second region includes an oxide including the metallic element.

### Configuration 13

The pattern formation method according to any one of Configurations 1 to 12, further comprising, after the process, a removal process of removing the first region, removing a portion of the first layer overlapping the first region, and removing at least a portion of the base body not overlapping the second region.

### Configuration 14

The pattern formation method according to any one of Configurations 1 to 13, wherein the metal compound includes an organic metal compound.

### Configuration 15

The pattern formation method according to any one of Configurations 1 to 13, wherein the metal compound includes trimethyl aluminum.

### Configuration 16

The pattern formation method according to any one of Configurations 1 to 7, wherein the metal compound includes chlorine and at least one selected from the group consisting of Ti, V, and W.

### Configuration 17

The pattern formation method according to, any one of Configurations 1 to 16, wherein a surface energy of the first layer is larger than a surface energy of the first polymer and smaller than a surface energy of the second polymer.

### Configuration 18

The pattern formation method according to any one of Configurations 1 to 17, wherein a direction from the first region toward the second region is along the base body.

### Configuration 19

A pattern formation material, comprising:

a polymer including a first chemical structure, the first chemical structure including carbon, hydrogen, and a first group; and

a solvent,

the first group including at least one of a vinyl group, a hydroxy group, or a first element,

the first element including at least one of a fluorine atom, a chlorine atom, a bromine atom, or a nitrogen atom,

the pattern formation material not including a carbonyl group, or a concentration of carbonyl groups in the pattern formation material being 0.0005 mol/g or less.

### Configuration 20

The pattern formation material according to Configuration 19, wherein

the first group includes at least one selected from the group consisting of vinyl alcohol, hydroxystyrene, and vinyl chloride,

the polymer further includes a second chemical structure,

the second chemical structure includes at least one selected from the group consisting of styrene, isobutylene, butadiene, and isoprene,

the polymer includes a random copolymer including the first chemical structure and the second chemical structure,

the polymer includes a first terminal,

the first terminal includes at least one selected from the group consisting of a hydroxy group, a thiol group, a trimethylsilyl group, and a hydrocarbon including a nitroxyl radical,

the solvent includes at least one selected from the group consisting of PGMEA (propyleneglycol monomethyl ether acetate), anisole, ethyl lactate, butyl acetate, and cyclohexanone, and

a concentration of the polymer in the pattern formation material is not less than 0.001 wt % and not more than 20 wt %.

According to the embodiments, a pattern formation method and a pattern formation material can be provided in which it is possible to improve the productivity.

Hereinabove, embodiments of the invention are described with reference to specific examples. However, the invention is not limited to these specific examples. For example, one skilled in the art may similarly practice the invention by appropriately selecting specific configurations of components included in the pattern formation method and the pattern formation material such as the polymer, the chemical structure, the precursor monomer, the block copolymer, the solvent, the metal compound etc., from known art; and such practice is within the scope of the invention to the extent that similar effects can be obtained.

Any two or more components of the specific examples may be combined within the extent of technical feasibility and are within the scope of the invention to the extent that the spirit of the invention is included.

All pattern formation methods and pattern formation materials practicable by an appropriate design modification by one skilled in the art based on the pattern formation method and the pattern formation material described above as the embodiments of the invention also are within the scope of the invention to the extent that the spirit of the invention is included.

Various modifications and alterations within the spirit of the invention will be readily apparent to those skilled in the art; and all such modifications and alterations should be seen as being within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A pattern formation method, comprising:
a preparation process of preparing a pattern formation material including a polymer including a first chemical structure, the first chemical structure including carbon, hydrogen, and a first group, the first group including at least one of a vinyl group, a hydroxy group, or a first element, the first element including at least one selected from the group consisting of fluorine, chlorine, and bromine, the pattern formation material not including a carbonyl group, or a concentration of carbonyl groups in the pattern formation material being 0.0005 mol/g or less;
a first layer formation process of forming a first layer on a base body, the first layer including the pattern formation material;
a block copolymer layer formation process of forming a block copolymer layer on the first layer, the block copolymer layer including a first polymer and a second polymer, the block copolymer layer formation process including forming a first region and a second region by causing phase separation of the first polymer and the second polymer, the first region including the first polymer, the second region including the second polymer, the second polymer including a carbonyl group; and
a contact process of causing the block copolymer layer to contact a metal compound including a metallic element.

2. The method according to claim 1, wherein the first group includes at least one selected from the group consisting of vinyl alcohol, hydroxystyrene, and vinyl chloride.

3. The method according to claim 1, wherein
the polymer further includes a second chemical structure, and
the second chemical structure includes at least one selected from the group consisting of styrene, isobutylene, butadiene, and isoprene.

4. The method according to claim 3, wherein the polymer includes a random copolymer including the first chemical structure and the second chemical structure.

5. The method according to claim 1, wherein
the polymer has a first terminal, and
the first terminal includes at least one selected from the group consisting of a hydroxy group, a thiol group, a trimethylsilyl group, and a hydrocarbon including a nitroxyl radical.

6. The method according to claim 1, wherein
the pattern formation material further includes a solvent,
the solvent includes at least one selected from the group consisting of PGMEA (propyleneglycol monomethyl ether acetate), anisole, ethyl lactate, butyl acetate, and cyclohexanone, and
a concentration of the polymer in the pattern formation material is not less than 0.001 wt % and not more than 20 wt %.

7. The method according to claim 1, wherein the contact process includes introducing the metal compound into the second region.

8. The method according to claim 1, wherein the contact process includes causing the block copolymer layer to contact either a liquid that includes the metal compound or a gas that includes the metal compound.

9. The method according to claim 1, wherein after the penetration process, a concentration of the metallic element in the first region is lower than a concentration of the metallic element in the second region, and a concentration of the metallic element in the first layer is lower than the concentration of the metallic element in the second region.

10. The method according to claim 1, wherein after the contact process, the metallic element is adsorbed to the carbonyl group.

11. The method according to claim 1, further comprising, after the contact process, a process to expose the block copolymer layer to an atmosphere including at least one selected from the group consisting of water, oxygen including a plasma state, and ozone.

12. The method according to claim 11, wherein after the process, the second region includes an oxide including the metallic element.

13. The method according to claim 1, further comprising, after the process, a removal process of removing the first region, removing a portion of the first layer overlapping the first region, and removing at least a portion of the base body not overlapping the second region.

14. The method according to claim 1, wherein the metal compound includes an organic metal compound.

15. The method according to claim 1, wherein the metal compound includes trimethyl aluminum.

16. The method according to claim 1, wherein the metal compound includes chlorine and at least one selected from the group consisting of Ti, V, and W.

17. The method according to claim 1, wherein a surface energy of the first layer is larger than a surface energy of the first polymer and smaller than a surface energy of the second polymer.

18. The method according to claim 1, wherein a direction from the first region toward the second region is along the base body.

19. A pattern formation material, comprising;
a polymer including a first chemical structure, the first chemical structure including carbon, hydrogen, and a first group; and
a solvent,
the first group including at least one of a vinyl group, a hydroxy group, or a first element,
the first element including at least one of a fluorine atom, a chlorine atom, a bromine atom, or a nitrogen atom,
the pattern formation material not including a carbonyl group, or a concentration of carbonyl groups in the pattern formation material being 0.0005 mol/g or less.

20. The material according to claim 19, wherein
the first group includes at least one selected from the group consisting of vinyl alcohol, hydroxystyrene, and vinyl chloride,
the polymer further includes a second chemical structure,
the second chemical structure includes at least one selected from the group consisting of styrene, isobutylene, butadiene, and isoprene,
the polymer includes a random copolymer including the first chemical structure and the second chemical structure,
the polymer has a first terminal,
the first terminal includes at least one selected from the group consisting of a hydroxy group, a thiol group, a trimethylsilyl group, and a hydrocarbon including a nitroxyl radical,
the solvent includes at least one selected from the group consisting of PGMEA (propyleneglycol monomethyl ether acetate), anisole, ethyl lactate, butyl acetate, and cyclohexanone, and
a concentration of the polymer in the pattern formation material is not less than 0.001 wt % and not more than 20 wt %.
